(19) United States
(12) Patent Application Publication
(10) Pub. No.: US 2024/0414897 A1
(43) Pub. Date: Dec. 12, 2024

(54) COOLER, INVERTER AND MOTOR VEHICLE

(71) Applicant: ZF Friedrichshafen AG, Friedrichshafen (DE)

(72) Inventors: Claudia Kleinschrodt, Bayreuth (DE); Moritz Faden, Bayreuth (DE)

(73) Assignee: ZF Friedrichshafen AG, Friedrichshafen (DE)

(21) Appl. No.: 18/734,715

(22) Filed: Jun. 5, 2024

(30) Foreign Application Priority Data
Jun. 6, 2023 (DE) 10 2023 205 274.1

(51) Int. Cl. H05K 7/20

(52) U.S. Cl. CPC H05K 7/20927; H05K 7/209

(57) ABSTRACT

Cooler for an inverter for a motor vehicle, wherein the cooler is configured for the arrangement of a plurality of power modules, comprising one or more heat sinks, which provide a cooling channel, wherein the cooling channel has an inlet and an outlet and is configured for a cooling fluid to flow through it, wherein at least one of the heat sinks has a cooling structure that engages into the cooling channel, wherein a cooling structure density is adapted to the thermal properties of the inverter and/or to the thermal properties of a power module. An inverter having such a cooler and a motor vehicle having such an inverter are also disclosed.

### CROSS-REFERENCE TO RELATED APPLICATION

This application claims priority to German Application No. DE 10 2023 205 274.1, filed on Jun. 6, 2023, the entirety of which is hereby fully incorporated by reference herein.

### FIELD

The present disclosure relates to a cooler for an inverter for a motor vehicle, to an inverter for a motor vehicle and to a motor vehicle.

### BACKGROUND

For the operation of electrically powered, in particular battery-electrically powered, motor vehicles, inverters are used. These convert direct current into alternating current in order to drive one or more electric motors. The power modules of the inverter generate large amounts of heat during operation, and this needs to be dissipated. Active liquid cooling systems are known in the prior art. Especially for motor vehicles, conflicting requirements compete with one another. On the one hand, a large amount of heat is provided during operation, which needs to be dissipated, but on the other hand the cooling itself, inter alia by circulation of the cooling fluid, requires energy. Although high cooling powers can be produced easily with a high throughput of the cooling fluid, the energy requirement is comparatively great since it is necessary to compensate for large pressure drops inside the cooling system.

In addition, coolers with uniform cooling structures are known in the prior art. The temperature of the cooling fluid is lowest at the inlet and increases toward the outlet. For this reason, the cooling effect in known coolers decreases from the inlet to the outlet.

### SUMMARY

It is therefore an object to provide an effective cooler which provides a high cooling power that is uniform for all power modules, and in which the flow of the cooling fluid through a cooling channel is configured in a particularly energy-saving fashion.

This object is achieved by a cooler according to the present disclosure. Such a cooler may comprise
one or more heat sinks, which provides or provide a cooling channel,
wherein the cooling channel has an inlet and an outlet and is configured for a cooling fluid to flow through it,
wherein at least one of the heat sinks has a cooling structure that engages into the cooling channel,
wherein a cooling structure density is adapted to the thermal properties of the inverter and/or to the thermal properties of a power module.

In particular, such a cooler is intended for use with an inverter or in a motor vehicle having an inverter. The cooler is configured for the arrangement or attachment of a plurality of power modules, in order to provide effective cooling.

The heat sink provides a housing or a part of a housing of the cooling channel. For example, the heat sink is configured in one piece. Alternatively, the heat sink is configured in multiple pieces. A plurality of heat sinks together form a housing and/or a cooling channel. Alternatively, one of the heat sinks is formed by a component of the inverter, for example a housing of the inverter. A plurality of heat sinks are arranged on one another, for example materially bonded, with a force fit or with a form fit, in particular by an adhesive bond, a solder connection, a hard solder connection, a weld connection or a screw connection. Optionally, a sealing element for sealing the cooling channel is arranged between the heat sinks. The heat sinks are, for example, formed from copper or stainless steel.

For example, a water-glycol mixture is used as the cooling fluid. The cooling fluid is introduced into the cooling channel at an inlet, flows through the cooling channel and is discharged from the cooling channel at an outlet. Inside the cooling channel, the cooling fluid absorbs heat that is generated by the power modules.

The cooling structure is on the one hand connected thermally conductively to one or more power modules and absorbs their heat. The heat is conveyed along the cooling structure, which protrudes into the cooling channel. The cooling fluid flowing past the cooling structure absorbs the heat and transports it away.

The inverter has thermal properties. The thermal properties are dictated by the structure of the inverter. This relates inter alia to the arrangement of the power modules, their power, the heat that they develop, their position along the cooler, etc. In a conventional structure of a cooler, which has a uniform cooling structure over the entire cooling channel, the effect occurs that the cooling fluid has a minimum temperature close to the inlet, which increases along the cooling channel toward the outlet. If all power modules generate the same or a similar amount of heat, the temperature of the cooling fluid increases toward the outlet. The cooling fluid can then only absorb heat at a higher temperature, and the capability of the cooling fluid to absorb heat consequently decreases. The power modules arranged further along in the cooling channel therefore have a higher temperature during operation of the inverter, and are therefore more greatly stressed.

The adaptation of the cooling structure makes it possible to influence the absorption of heat by the cooling fluid in such a way that the cooling fluid absorbs the same or a similar amount of heat from the various power modules over the entire cooling channel. The cooling power is the same for all power modules, irrespective of their position in relation to the heat sink. The further embodiments describe specific configuration variants of such cooling structures.

A corresponding adaptation of the cooling structure to the thermal properties of a power module allows optimal thermal transfer of the generated heat from the semiconductor elements of the power module to the cooling structure. The thermal properties of a power module relate inter alia to the arrangement of the heat sources or semiconductor elements inside the power module, their type, their power, the heat that they develop during operation, etc. Specific alternative embodiments for the adaptation of the cooling structure to the thermal properties of a power module are also explained below.

Advantageous configuration variants are described below.

Particularly advantageously, the cooling structure density increases from the inlet to the outlet.

The cooler structure density describes a measure of the capability of the cooler structure to transfer heat to the cooling fluid. A higher cooler structure density has better thermal transmission to the cooling fluid than a low cooler structure density. The cooler structure density may inter alia be adapted by the number of cooling structure elements inside a region, the thickness of the cooling structure elements, the length of the cooling structure elements, the shape of the cooling structure elements and/or the arrangement of the cooling structure elements with respect to one another, etc. A cooling structure element is configured for example as a pinfin, as a plate, as a labyrinth or as another structure. Different cooling structure elements may be combined with one another. Pinfins may for example be configured as cylinders, elliptical cylinders, hexagonal cylinders, etc. The shape of the cooling structure elements may be formed parallel, conically or in a different fashion. The thermal transfer may be adapted by adapting one or more parameters of the cooling structure along the cooling channel.

The absorption of heat in the inlet region is selected to be comparatively lower than in the outlet region, this in turn being compensated for by the increasing coolant temperature. The thermal transfer may be adapted for all power modules according to requirements, and is preferably the same for all power modules. The thermal transfer is in this context normalized to the thermal power of the respective power module or semiconductor element, so that different power modules or semiconductor elements may also be cooled to a different extent according to requirements in order to allow optimal operation with the lowest possible temperature.

Particularly advantageously, a region, assigned to a power module, of the cooling structure has regions with a higher cooling structure density.

Besides the regions with a higher cooling structure density, the cooler has regions with a low cooling structure density. Such adaptation of the cooling structure density allows the regions of the power module that develop more heat, in particular the semiconductor elements, to have an improved thermal transfer into the cooling channel. A heat path that is as direct as possible is thereby provided. In the regions that develop less heat, on the other hand, a pressure loss is reduced by a lower cooling structure density.

Particularly advantageously, in a region, assigned to the power module, of the cooling structure, a region with a higher cooling structure density is assigned to a heat source or to a semiconductor element of the power module and/or lies opposite the heat source or the semiconductor element.

The generation of heat does not take place homogeneously inside the power module, but occurs pointwise due to the semiconductor elements. The dissipation of heat in the regions that generate heat is optimized by an assigned increase of the cooling structure density.

Particularly advantageously, the heat sink is configured in one piece or multiple pieces, in particular two pieces.

In this regard, reference is made to the further embodiments of the patent specification.

Particularly advantageously, one power module is arranged on the first heat sink and another power module is arranged on the second heat sink.

This makes it possible to increase the number of power modules to be cooled by a cooler. The power modules are preferably arranged alternately opposite one another along the cooling channel. Preferably, a power module of the one heat sink is arranged offset along the flow direction of the cooling fluid relative to an opposite heat sink. An input of heat due to the power modules therefore takes place at different locations in relation to a flow direction along the cooling channel. The positions of the power modules are arranged offset along the flow direction through the cooling channel. Preferably, the power modules are arranged opposite only with an offset along the flow direction of the cooling channel. Particularly advantageously, a cooling structure is formed on the first heat sink and a cooling structure is formed on the second heat sink.

A cooling structure is preferably formed on the heat sink on which the associated power module can be arranged or is arranged. The thermal transfer to the cooling structure is therefore optimal. The cooling structures of the heat sinks preferably engage complementarily into one another. By the offset of mutually opposite power modules along the cooling channel, on the one hand the input of heat is distributed uniformly along the cooling channel. In addition, the offset allows cooling structure elements of the one heat sink to engage between cooling structure elements of the other heat sink.

Particularly advantageously, the cooling structure has a bypass.

A bypass allows a flow of cooling fluid along the cooling channel almost without any pressure loss. Due to such a bypass, it is possible to divert a fraction of the cooling fluid past a cooling structure so that it absorbs no heat, or only a lower fraction of heat. In a portion of the cooling channel lying further behind, this cooling fluid may be used with a lower temperature in order to effectively cool power modules arranged on the outlet side. A fraction of the cooling fluid is thereby saved for power modules arranged further behind. The fraction of the cooling fluid that flows through the bypass may be adapted by the configuration of the cooling structure and/or by the cross section of the bypass.

Particularly advantageously, a cross section of the bypass decreases from the inlet to the outlet.

On the inlet side, the cross section of the bypass in comparison with the cross section of the cooling channel is larger than on the outlet side. The cross section of the bypass preferably decreases constantly and/or monotonically, for example linearly, along the cooling channel. A fraction of the colder coolant available is therefore respectively used for the power modules along the cooling channel.

Particularly advantageously, the bypass intersects the cooling channel.

By the intersection of the cooling channel, the already heated cooling fluid is mixed with the cooling fluid of the bypass, so that a cooling fluid that is colder on average is provided for subsequent cooling structures. An intersection direction of the bypass preferably extends perpendicularly to the direction of extent of the cooling structure and at an angle with respect to the flow direction of the cooling channel. The angle is preferably between 20° and 70°, in particular between 30° and 60°. Alternatively or in addition, an intersection direction of the bypass preferably extends at an angle with respect to the direction of extent of the cooling structure and parallel to the flow direction of the cooling channel. Such an angle is expediently between 20° and 70°, in particular between 30° and 60°. Advantageously, an intersection of the bypass takes place from a wall of the one cooling structure to a wall of the other cooling structure.

The object is also achieved by an inverter according to the present disclosure. Such an inverter may comprise a cooler as disclosed herein and/or according to one of the preceding embodiments relating to the cooler.

The object is also achieved by a motor vehicle as disclosed herein. Such a motor vehicle may comprise an inverter as disclosed herein.

The cooler and the inverter will be explained by way of example below with the aid of several figures.

### BRIEF DESCRIPTION OF THE DRAWINGS

FIG. 1 shows a cooler with an optimized cooling structure;

FIG. 2 shows a cooling structure density distribution of a cooler for a single power module;

FIG. 3 shows a further cooler with a different cooling structure;

FIG. 4 shows an enlarged partial representation of the cooler of FIG. 3.

### DETAILED DESCRIPTION

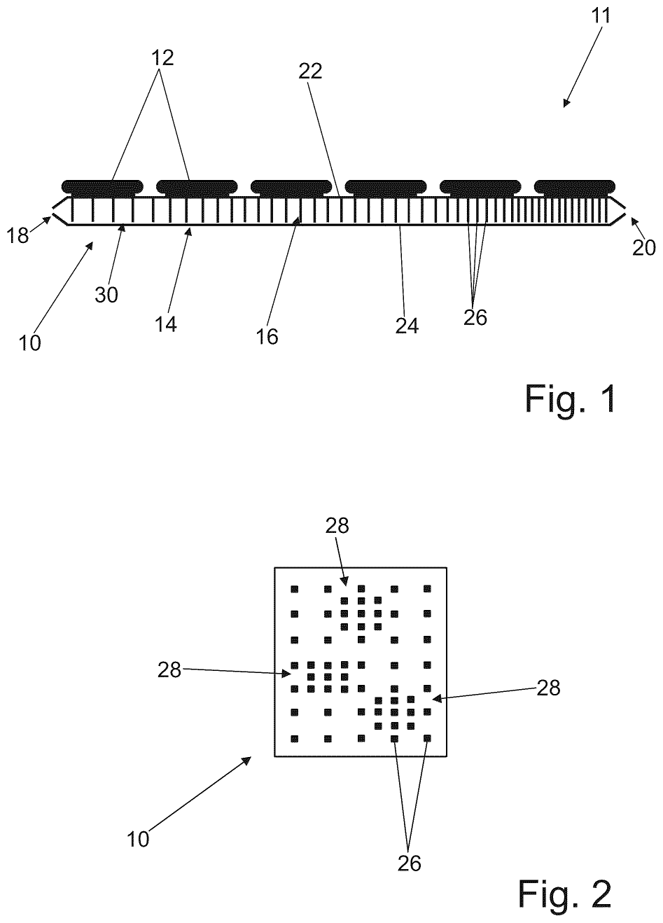

FIG. 1 represents a cooler 10 for an inverter 11, the representation being schematic and very simplified. Such an inverter is arranged in the vehicle between a battery storage unit, which provides direct current, and an electric motor that is operated with alternating current. The inverter converts between direct current and alternating current, so that energy from the battery storage unit can be provided in order to power the electric motor or energy generated in the electric motor can be stored in the battery. The inverter comprises a plurality of power modules 12, each of which has one or more semiconductor elements. The functionality of such power modules is widely known and will not be explained in further detail.

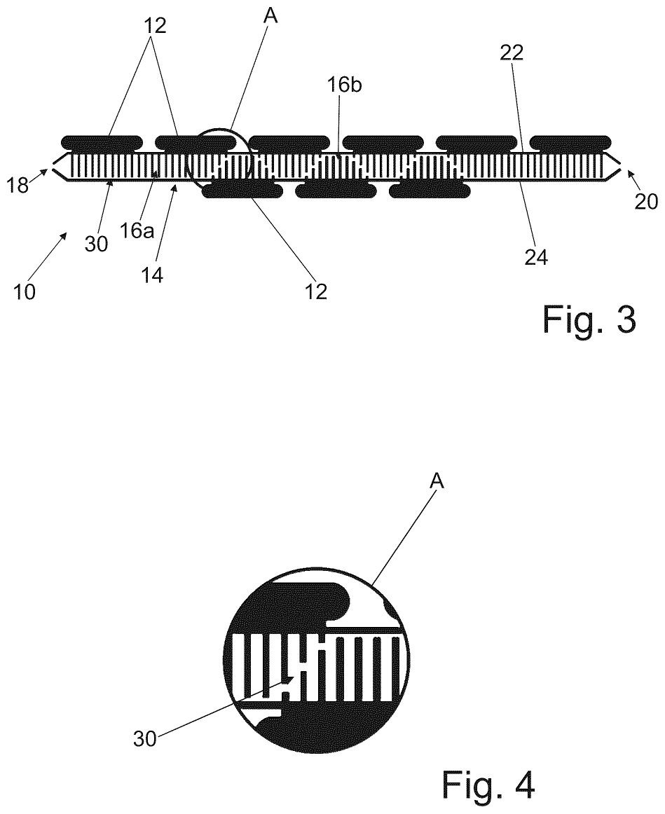

The power modules 12, in particular their semiconductor elements, generate heat during operation, which is dissipated by active cooling. The cooler 10 has a cooling channel 14, into which a cooling structure 16 engages. The cooling channel 14 is configured in such a way that it is closed, and it has an inlet 18 on one side and an outlet 20 on the other side. The cooling fluid flows into the cooling channel 14 at the inlet 18, flows through the cooling channel 14 and flows out of the cooling channel 14 at the outlet 20. In FIGS. 1 and 3, the inlet 18 is represented on the left and the outlet 20 is represented on the right. The cooling fluid, for example water, flows around the cooling structure 16. The cooling structure 16 transports the generated heat into the cooling channel 14 and releases it to the cooling fluid.

The cooler 10 has a first heat sink 22 and a second heat sink 24, which are connected to one another and form the cooling channel. The two heat sinks form a housing of the cooler 10. The first heat sink 22 and the second heat sink 24 are sealed with one another in a gas-tight fashion, formed for example from copper and materially bonded to one another. Expediently, the heat sinks are electroplated. This alternative embodiment is, however, selected merely by way of example. The heat sink may, for example, also be configured in one piece. In a further variant, a component of the inverter, for example an inverter housing, forms a receptacle or a mating piece for the heat sink. Accordingly, the component of the inverter, for example the inverter housing, forms a heat sink as an additional component function. The cooling structure 16 and several variants will be explained in detail below by way of example.

The cooling structure 16 is, as represented in FIG. 1, formed by pinfins 26. Alternatively, the cooling structure 16 is formed by plates, labyrinths or other structures. These and also other types of cooling structures may be combined with one another.

The heat generated by the power modules 12 is dissipated to the cooler at various locations. The generation of heat may be the same for all power modules, each power module may generate a different amount of heat, or else only one or more power modules may generate different amounts of heat. Furthermore, the capability of the cooling fluid to absorb heat is dependent on its temperature. The temperature of the cooling fluid is in principle lower at the inlet 18 than at the outlet 20.

The cooling structures 16 represented are adapted to the thermal properties of the inverter.

By way of example, the power modules 12 in FIG. 1 all generate the same amount of heat. A cooling structure density is low at the inlet 18 and high at the outlet 20. The cooling structure density increases along the flow direction through the cooling channel. The increase of the cooling structure density allows uniform dissipation of the amount of heat along the cooling channel even in the event of an increasing coolant temperature. The cooling power is the same for all power modules 12. Specifically, the increase of the cooler structure density is provided in FIG. 1 by an increasing number of pinfins that are assigned to a power module. When considering the neighboring power modules, the number of pinfins of the neighboring power module on the inlet side is less and that of the neighboring power module on the outlet side is greater.

In addition, the pressure loss is reduced because of the lower cooler structure density on the side of the inlet 18. A pressure loss that is as low as possible over the entire cooling channel saves energy for the circulation of the cooling fluid.

The adaptation of the number of pinfins to the thermal properties of the inverter is selected by way of example for the adaptation of the cooler structure density. In principle, other parameters, for example the length of the pinfins, the shape of the pinfins, the thickness of the pinfins, etc. may also be varied. A combined adaptation of these or further parameters is also possible.

FIG. 2 represents the adaptation of the cooling structure density to the thermal properties of a power module 12 by way of example and in excerpts for a single power module. In particular, a plan view of the cooling structure is represented. This adaptation may take place in addition or as an alternative to the adaptation of the cooling structure density to the thermal properties of the inverter. The power module comprises one or more semiconductor elements, which are arranged distributed on the power module. The generation of heat does not take place in a homogeneously distributed fashion over the entire power module 12, but pointwise at the semiconductor elements, and is then distributed inside the power module 12. The heat generation of the various semiconductor elements of the power module 12 may be the same or mutually different.

According to FIG. 2, the cooling structure density is higher in relation to a power module 12 in the region of the heat generators and/or of a semiconductor element than in other regions. For example, the other regions do not have any such heat sources. The cooler therefore has regions with a higher cooling structure density 28, which are assigned to the heat sources and/or semiconductor elements and/or lie opposite them inside the cooler 14. The remaining regions are configured with a lower cooling structure density. The cooler 10 therefore has a cooling structure density distribution in relation to a power module 12. The cooling structure density distribution has an increased cooling structure density in the region of heat sources and/or semiconductor elements. The increase of the cooling structure density in the regions of the heat sources and/or semiconductor elements constitutes direct and maximally efficient dissipation of the generated heat.

For example, a semiconductor element, in particular a transistor, represents such a region as a heat generator, the cooler structure density that lies directly opposite the semiconductor element in the cooling channel having a higher cooler structure density than surrounding regions. For example, a cooler structure density in the edge regions of the power module is less than in a region in which a semiconductor element is arranged.

The cooler structure density in relation to the adaptation to the thermal properties of a power module takes place substantially identically to the above-described adaptation of the cooler structure density to the thermal properties of the inverter. In relation to pinfins, adaptation could for example take place by means of the length, thickness and/or shape of the pinfins.

In a combination of the adaptation of the cooler structure density to the thermal properties of a plurality of identical power modules and to the thermal properties of the inverter, cooler structure density arrangements along the cooling channel, which are identical for each power module, are for example formed in relation to each power module, the average density of the cooler structure density arrangement increasing from the inlet to the outlet.

Advantageously, a cooling structure 16 as shown by way of example in FIG. 1 extends from one wall of the cooling channel to an opposite wall of the cooling channel. Advantageously, the cooling structure has a distance from the opposite wall, comes in direct contact therewith or is connected thereto with a form fit, force fit or materially. In the case mentioned first, a bypass, which will be explained in more detail below, may be provided. In a configuration with two or more heat sinks, the walls are formed by mutually opposite heat sinks. In a one-piece configuration, the heat sink integrally forms the mutually opposite walls.

According to FIG. 1, all power modules 12 are arranged on the first heat sink 22. The cooling structure 16 is formed by the first heat sink 22.

An alternative arrangement of the power modules and configuration of the cooling structure are represented in FIG. 3. The power modules 12 are arranged on two sides of the cooler 10. Power modules 12 are arranged both on the first heat sink 22 and on the second heat sink 24. The cooling structures 16a, 16b assigned to the power modules 12 extend from the heat sink 22, 24 on which the power module 12 is arranged into the cooling channel 14. The cooling structures 16a, 16b are configured in such a way that they engage complementarily in one another. Power modules 12 lying opposite one another are arranged mutually offset along the cooling channel, such that the heat sources are distributed uniformly along the cooling channel 14.

In the embodiment according to FIG. 3, there is in principle adaptation of the cooling structures 16a, 16b to the thermal properties of the inverter and/or to the thermal properties of the power modules 12, even though this or these is/are not represented in the schematic drawing.

A bypass 30 is advantageously formed on a cooling channel 14. Such a bypass 30 is configured by a free space along the cooling channel 14. As represented in FIGS. 1 and 3, this free space extends for example between an end region of the cooling structure 16 and an opposite wall. Alternatively or in addition, such a bypass 30 is arranged laterally next to the cooling structure with respect to the cooling structure. The bypass 30 allows the cooling fluid to flow with little resistance and without pressure loss through the cooling channel 14. The cooling fluid flowing along the bypass 30 experiences no heating, or only minor heating, by the cooling structure. This unheated or only slightly heated fraction of the cooling fluid is available in the rear region of the cooler 14 in order to achieve better cooling of the power modules 12 on the outlet side.

The fraction of the cooling fluid passing the cooling structure via the bypass 30 may be adapted by the cross-sectional area of the bypass. The adaptation preferably takes place by adapting a distance between the cooling structure and the opposite wall.

Expediently, a cross-sectional area decreases from the inlet 18 to the outlet 20. This may for example be achieved in FIG. 1 by a length of the pinfins being shorter on the inlet side than on the outlet side, in particular decreasing from the inlet to the outlet. The adaptation of the length of the pinfins takes place for example continuously and/or in steps and/or linearly along the flow direction through the cooling channel 14.

Likewise advantageous is an intersection of the cooling channel 14 by the bypass 30. This is shown by way of example in FIG. 3 and in an enlarged representation in FIG. 4. By an intersection of the cooling channel, the colder cooling fluid conveyed in the bypass is mixed with the already heated cooling fluid that flows through the cooling structure. A lower average coolant temperature in the outlet region of the cooler 10 and therefore an improved cooling power for power modules 12 arranged on the outlet side may thereby be provided.

The various measures for optimizing the cooling power with the lowest possible pressure loss may be used both individually and in any desired combination with one another. The preceding comments are not restricted to the exemplary embodiments and representations.

### LIST OF REFERENCE SIGNS

10 cooler
11 inverter
12 power module
14 cooling channel
16,a,b cooling structure
18 inlet
20 outlet
22 first heat sink
24 second heat sink
26 pinfin
28 regions with a higher cooling structure density
30 bypass

1. A cooler for an inverter for a motor vehicle, wherein the cooler is configured for an arrangement of a plurality of power modules, the cooler comprising:
one or more heat sinks configured to provide a cooling channel, wherein the cooling channel has an inlet and an outlet and is configured for a cooling fluid to flow through it,
wherein at least one of the one or more heat sinks has a cooling structure that engages into the cooling channel, and
wherein a cooling structure density is adapted to thermal properties of the inverter and/or to the thermal properties of a power module.

2. The cooler according to claim 1, wherein the cooling structure density increases from the inlet to the outlet.

3. The cooler according to claim 1, wherein a region assigned to the power module of the cooling structure has regions with a higher cooling structure density.

4. The cooler according to claim 3, wherein, in the region assigned to the power module of the cooling structure, a region with a higher cooling structure density is assigned to a heat source or to a semiconductor element of the power module and/or lies opposite the heat source or the semiconductor element.

5. The cooler according to claim 1, wherein a first cooling structure is formed on a first heat sink, and wherein a second cooling structure is formed on a second heat sink.

6. The cooler according to claim 1, wherein the cooling structure has a bypass.

7. The cooler according to claim 6, wherein the bypass intersects the cooling channel.

8. The cooler according to claim 6, wherein a cross section of the bypass decreases from the inlet to the outlet.

9. The cooler according to claim 2, wherein a region assigned to the power module of the cooling structure has regions with a higher cooling structure density.

10. The cooler according to claim 9, wherein, in the region assigned to the power module of the cooling structure, a region with a higher cooling structure density is assigned to a heat source or to a semiconductor element of the power module and/or lies opposite the heat source or the semiconductor element.

11. The cooler according to claim 2, wherein a first cooling structure is formed on a first heat sink, and wherein a second cooling structure is formed on a second heat sink.

12. The cooler according to claim 2, wherein the cooling structure has a bypass.

13. The cooler according to claim 12, wherein the bypass (30) intersects the cooling channel (14).

14. The cooler according to claim 12, wherein a cross section of the bypass decreases from the inlet to the outlet.

15. The cooler according to claim 14, wherein the bypass intersects the cooling channel.

16. The cooler according to claim 3, wherein a first cooling structure is formed on a first heat sink, and wherein a second cooling structure is formed on a second heat sink.

17. The cooler according to claim 3, wherein the cooling structure has a bypass.

18. The cooler according to claim 17, wherein a cross section of the bypass decreases from the inlet to the outlet.

19. An inverter for a motor vehicle, comprising:
the cooler according to claim 1.

20. A motor vehicle comprising:
the inverter according to claim 19.
